(19) United States
(12) Patent Application Publication
(10) Pub. No.: US 2008/0131612 A1
(43) Pub. Date: Jun. 5, 2008

(54) Method for making an environment-resistant and thermal barrier coating system on a component

(75) Inventors: Yiping Hu, Greer, SC (US); Derek Raybould, Denville, NJ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/606,544

(22) Filed: Nov. 30, 2006

(51) Int. Cl. B05D 1/36; B05D 3/02; B05D 3/12; C23C 14/30; C23C 4/10

(52) U.S. Cl. 427/454; 427/372.2; 427/446; 427/596; 427/299

(57) ABSTRACT

Methods are provided for forming a coating system on a gas turbine component. In one embodiment, and by way of example only, the method includes cold spraying a material onto the component surface to form an overlay coating, the material comprising MCrAlY, wherein M comprises a constituent selected from the group consisting of Ni, Co, or Fe, or combinations of Ni, Co, and Fe. Then, the overlay coating is heat treated. The overlay coating is then shot peened and vibro polished. A thermal barrier coating is then applied onto the overlay coating to form the coating system via air plasma spaying or electron beam physical vapor deposition technique.

### TECHNICAL FIELD

The present invention relates to coating metallic substrates, such as gas turbine engine components, with a coating having good bond strength, corrosion and oxidation as well as thermal resistance and, more particularly, to methods of forming environment-resistant and thermal barrier coating systems on the components.

### BACKGROUND

Gas turbine engines, such as turbofan gas turbine engines, may be used to power various types of vehicles and systems, such as, for example, aircraft. During engine operation, generally, compressed air is mixed with fuel and burned, and the expanding hot combustion gases are directed against stationary turbine vanes in the engine. The vanes turn the high velocity gas flow partially sideways to impinge on turbine blades mounted on a rotationally mounted turbine disk or wheel.

The force of the impinging gas causes the turbine disk to spin at high speeds and to produce power. When the high speed gas is passed out of the aft end of an aircraft turbine engine, forward thrust is created. Thus, the components of the engine are subjected to both high stress loadings and high heat (often in excess of 1090° C.). The high stress and heat can cause erosion, oxidation, corrosion, and thermal fatigue cracks in the components, resulting in unacceptably high rates of degradation.

To protect the components from the above, environment-resistant coatings and thermal barrier coatings may be used. Environment-resistant coatings are typically formed by depositing an appropriate coating material, such as MCrAlY, onto the component using one of various thermal spraying or depositing processes. Examples of thermal or depositing processes include, low pressure plasma spraying (LPPS), high velocity oxygen fuel (HVOF) spraying, air plasma spraying, and electric arc wire spraying, and electron beam physical vapor deposition (EBPVD). The thermal barrier coating, which may be made of ceramic materials such as yttria partially stabilized zirconia, is then deposited directly over the environment-resistant coating. Various processes, such as plasma spraying process, plasma-assist chemical vapor deposition, and electron beam plasma vapor deposition, are typically used to form the thermal barrier coating.

Although employing the above-mentioned processes produces environment-resistant coatings or top coat/bond coat systems that are useful in some circumstances, they may not be suitable in other circumstances. In particular, production costs and time limitations may deter application of the coatings by the aforementioned processes, such as low pressure plasma spraying, as they may be generally costly and time-consuming to perform. Additionally, in some cases, the coatings formed by the above-described processes, such as air plasma spraying and high velocity oxygen fuel spraying processes, may not be suitably withstanding the high temperatures for an extended duration, because the extended exposure may cause the coatings to degrade.

Hence, there is a need for a coating system that protects a component from temperatures that are equal to or greater than at least 1090° C. Additionally, there is a need for a method of making the coating system that is relatively inexpensive and simple to perform.

### BRIEF SUMMARY

The present invention provides methods of forming a coating system on a gas turbine component.

In one embodiment, and by way of example only, the method includes cold spraying a material onto the component surface to form an overlay coating, the material comprising MCrAlY, wherein M comprises a constituent selected from the group consisting of Ni, Co, Fe or combinations thereof. Then, the overlay coating is heat treated. The overlay coating is then shot peened and vibro polished. A thermal barrier coating is then applied over the overlay coating to form the coating system.

In another embodiment, and by way of example only, a first powder is cold sprayed onto the component surface to form an overlay coating. The first powder comprises MCrAlY. The overlay coating is heat treated and then shot peened and vibro polished. A second powder is then air plasma sprayed over the overlay coating to form the thermal barrier coating.

In still another embodiment, and by way of example only, a first material is cold sprayed onto the component surface to form an overlay coating. The first material comprises MCrAlY. The overlay coating is heat treated, shot peened, and vibro polished. Then, a second material is electron beam physical vapor deposited over the overlay coating to form a thermal barrier coating.

Other independent features and advantages of the preferred methods will become apparent from the following detailed description, taken in conjunction with the accompanying drawings which illustrate, by way of example, the principles of the invention.

### BRIEF DESCRIPTION OF THE DRAWINGS

FIG. 1 shows a cross section view of a portion of a substrate that includes a coating system formed thereon;

FIG. 2 is a flow diagram showing an exemplary method for forming the coating system;

FIG. 3 is a schematic of an exemplary cold gas-dynamic spray system that may be used to implement the method shown in FIG. 2; and

FIG. 4 is a graph comparing a cold spray coated substrate and a low pressure plasma spray coated substrate when subjected to static oxidation at 2000° F. (1093° C.).

### DETAILED DESCRIPTION OF A PREFERRED EMBODIMENT

The following detailed description of the invention is merely exemplary in nature and is not intended to limit the invention or the application and uses of the invention. Furthermore, there is no intention to be bound by any theory presented in the preceding background of the invention or the following detailed description of the invention.

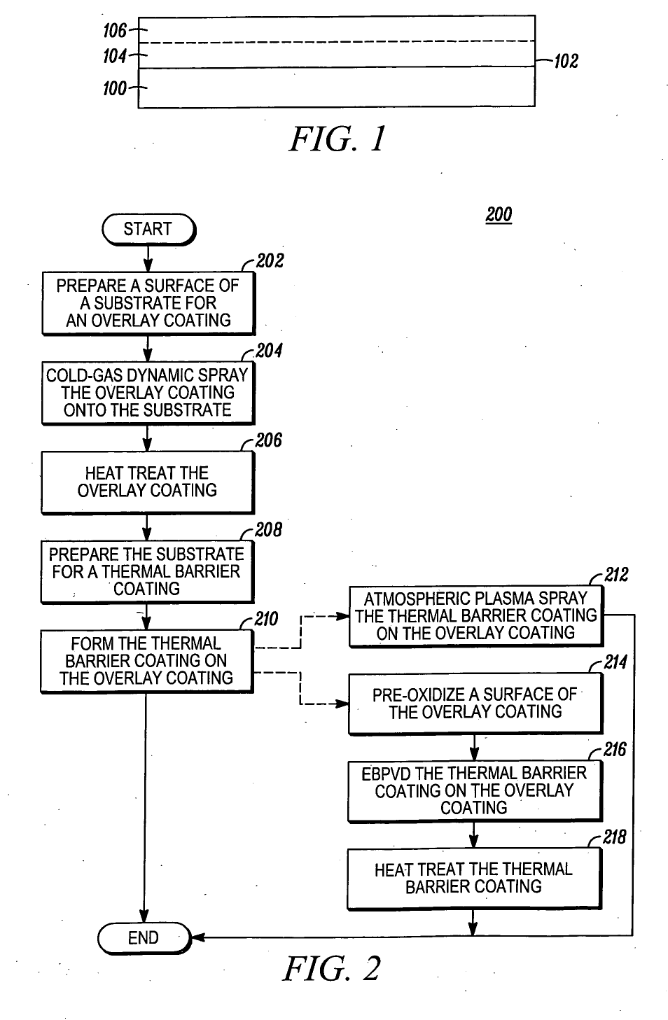

FIG. 1 shows a cross section view of a portion of a substrate 100 that includes a coating system 102 formed thereon. The substrate 100 may be any one of numerous components that may be subjected to high temperatures and that may need a coating for protection therefrom. For example, the substrate 100 may be a gas turbine engine component, such as a hot-section turbine airfoil, such as a turbine vane or blade, or a combustion liner.

The coating system 102 includes an overlay coating 104 and a thermal barrier coating 106. The overlay coating 104 is preferably made of a material that protects the substrate 100 from the environment attack. Additionally, the overlay coating 104 acts as a bond coat onto which the thermal barrier coating 106 is deposited. Suitable materials of which the overlay coating 104 may include, but are not limited to MCrAlY and MCrAlYX, M being Ni, Co, Fe or combinations of Ni, Co and Fe, and X being additive elements such as Hf, Si, Zr, Re, Pt and others individually or in combination thereof.

As alluded to above, the thermal barrier coating 106 is formed over the overlay coating 104 and is bonded thereto. The thermal barrier coating 106 provides heat resistance even when the substrate 100 is exposed to extremely high temperature, such as, above 1090° C. The coating material 106 may be any one of numerous suitable materials. Examples include, but are not limited to, ceramic materials such as zirconia, (ZrO₂), yttria (Y₂O₃), or other oxides like La₂Zr₂O₇, and yttria partially stabilized zirconia (YSZ) such as 6-8 wt. % YSZ.

FIG. 2 is a flow diagram showing an exemplary method 200 for forming the coating system 102. First, a surface of the substrate 100 is prepared for an overlay coating application, step 202. For example, the surface of the substrate 100 may be machined, cleaned, and/or grit-blasted with aluminum oxides. In some embodiments, the substrate 100 is a turbine airfoil having a cooling passage and exit holes formed therethrough. In these cases, the pre-spraying preparations may include plugging the exit holes with a low melting-point filler or material, such as wax, solder, or a Woods metal.

Next, the overlay coating 104 is formed on the substrate 100 using a cold gas-dynamic spraying process (also known in the art as “cold-spraying”), step 204. In this regard, particles of a powdered material suitable for forming the overlay coating 104 are applied to the substrate 100 at a temperature that is well below the powdered material melting point. The kinetic energy of the particles on impact with the substrate 100, rather than particle temperature, causes the particles to plastically deform and bond with the substrate 100 surface and to cohere with the solid splats previously and subsequently bonded to the substrate 100 surface. Neither the particles nor the substrate 100 melt. Therefore, bonding to the substrate 100 surface, as well as deposition buildup, takes place as a solid state process with insufficient thermal energy to transform the solid powders to molten droplets.

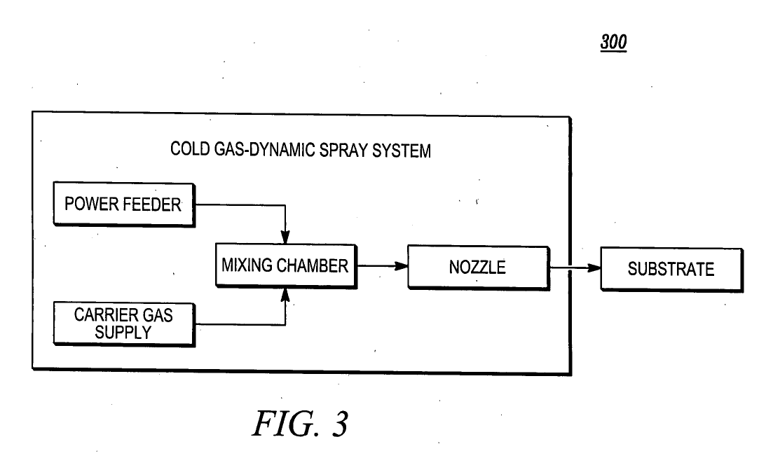

The cold gas-dynamic spray process may be performed using any one of numerous conventional cold gas-dynamic spraying systems. One exemplary cold gas-dynamic spray system 300 is illustrated diagrammatically in FIG. 3. The system 300 is illustrated as a general scheme, and additional features and components can be implemented into the system 300 as necessary. The main components of the cold-gas-dynamic spray system 300 include a powder feeder for providing coating materials, a carrier gas supply (typically including a heater) for heating and accelerating powder materials, a mixing chamber and a convergent-divergent nozzle. In general, the system 300 transports the powder mixtures with a suitable pressurized gas to the mixing chamber first, and then the particles are accelerated by the pressurized carrier gas, such as air, helium, nitrogen, or mixtures thereof, through the specially designed nozzle, to direct toward a targeted surface on a turbine component. When the particles strike the target surface, converted kinetic energy causes plastic deformation of the particles, which in turn causes the particles to form a bond with the target surface and to cohere with the solid splats previously and subsequently bonded to the target surface. Thus, the cold gas-dynamic spray system 300 can deposit the powder materials to the substrate 100 surface and thereby form the overlay coating 104 on the component.

One particular embodiment is described in U.S. Pat. No. 5,302,414, entitled “Gas-Dynamic Spraying Method for Applying a Coating”, incorporated herein by reference, that discloses an apparatus designed to accelerate materials having a particle size of between about 5 to about 50 microns to supersonic speed. A carrier gas is used to spray the particles through a Laval nozzle at a velocity ranging between about 300 and about 1200 m/s. The carrier gas is heated to between about 300° C. and about 400° C., but expansion of the gas as it travels through the nozzle causes the particles to cool. The particles therefore return to near ambient temperature by the time it reaches the targeted substrate surface.

In other embodiments, the cold spray process includes the steps of pre-heating the particles to temperatures that are higher than those used in conventional cold spray processes so that the particles impact the substrate at temperatures above ambient temperature, but still well below the particles' melting point. These processes may be grouped with cold spray processes, but may, in some cases, be known sub-grouped by those skilled in the art as “warm spray” processes. Ideally, the particles are heated so that they impact the substrate at a temperature that is between about 100° C. and a temperature that is below about half of the coating material melting point in ° C. Consequently, the particles are thermally softened and kinetic energy is still employed to bond the particle to the substrate. The particles do not need to be accelerated to velocities that are as high as those used in cold spray processes. Warm spray systems can use a carrier gas other than helium because lower impact velocities and pressures are required. Use of other cheap gases like nitrogen significantly reduces operating costs. In some warm spray systems, a preheated nozzle or substrate may be employed. The substrate may be heated to a temperature that is between about 100° C. and below a temperature that is about half the melting point of the substrate in ° C. or a temperature that is about half the melting point of the particles in ° C., which ever is the lower.

As mentioned above, a powder form of the overlay coating 104 material is applied to the substrate 100. The powder may include a single metallic element or may include mechanical alloying and/or pre-alloyed materials, and the system 300 can deposit multiple layers of different metallic materials having different densities and strengths as well as special properties. It will be appreciated that the powder may be pre-alloyed, so that all of the elements are uniformly distributed within each powder particle, or powders of each separate element may be mechanically mixed together in the required ratio. Both approaches have advantages. For example, admixed powders are much less expensive than pre-alloyed powders. However, in some cases one or more of the powders, which may be fine metal powders, may be potentially explosive, costly, or otherwise hazardous or inefficient to handle in a relatively pure form. In such a case, safety or economic concerns would favor a pre-alloyed powder that only contains a small percentage of such metals.

In embodiments in which the substrate 100 is a turbine airfoil having exit holes filled with low melting point filler material, the overlay coating 104 is formed over the filled exit holes. Because the overlay coating 104 is cold or warm sprayed onto the substrate 100, the filler material remains into the exit holes without melting. The filler material can then be subsequently removed by melting. Wax and solder filler materials can have melting points of around 100 to 200° C., depending on the particular composition. The melting point of Woods metal filler material, which has a eutectic composition, is about 70° C. Similar low melting point eutectic compositions may also be used as filler materials. Portions of the overlay coating 104 that are formed over the exit holes are unsupported and easily broken away from the rest of the coating 104. For example, the unsupported portions may be broken either by thermal shock, thermal cycling, over pressurizing the exit holes or by mechanical means such as grit blasting or shot peening the substrate 100 to remove the unsupported portion. The cost of individually re-drilling the exit holes is avoided, thereby significantly reducing manufacturing costs.

Referring back to FIG. 2, after the overlay coating 104 is deposited onto the substrate 100, the substrate 100 may be heat treated, step 206. The heat treatment is performed at an appropriate temperature for a suitable duration to thereby improve the metallurgical integrity of the deposited overlay coating 104. The particular temperature and duration of the heat treatment depends on the particular material used for the overlay coating 104. For example, in cases in which the overlay coating 104 is made of MCrAlYX, the coating 104 is heat treated at a temperature between about 1000° C. and about 1150° C. for between about 1 and about 16 hours. In one exemplary embodiment, the coating is heat treated at about 1100° C. for about 4 hours.

Next, the substrate 100 surface is prepared to receive a thermal barrier coating 106 thereon, step 208. The surface is preferably cut-wire shot peened and vibratory polished with alumina media, however, any other suitable finishing technique may be used such that the overlay coating 104 has a surface finish roughness average of between about 1 to 20 microns and preferably about 2.0 microns.

The thermal barrier coating 106 is then formed over the overlay coating 104, step 210. The deposition technique by which the thermal barrier coating 106 is formed may depend, at least in part, on the shape and complexity as well as function of the substrate 100. For example, in one exemplary embodiment in which the substrate 100 is a combustion liner, a powder form of the material used to form the thermal barrier coating 106, such as powdered 6-8 wt. % YSZ, may be atmospheric plasma sprayed onto the overlay coating 104, step 212.

In another exemplary embodiment in which the substrate 100 is a turbine blade or vane, at least a portion of the overlay coating 104 may first be pre-oxidized to obtain a thin layer of pure alumina scale, or thermally grown oxide (TGO), step 214. Pre-oxidized process may be performed using anyone of numerous techniques, however, in some cases, a thin oxidation layer may be preferably thermally grown on the overlay coating 104. For example, the overlay coating 104 may be heat treated at a temperature of about 1100° C. for about 1-2 hours such that the surface thereof will react with oxygen species that may be present in the air. Subsequently, the oxidized overlay coating is coated with the thermal barrier coating 106 material via electron beam physical vapor deposition, step 216. In one exemplary embodiment, about 4 mm of about 6-8 wt. % YSZ is deposited onto the pre-oxidized overlay coating to form the thermal barrier coating 106

The following examples demonstrate the effectiveness of the coating system 102 described above. These examples should not be construed as in any way limiting the scope of the invention

### EXAMPLE 1

A powder made up of standard MCrAlY, specifically, Co32Ni21Cr8Al0.5Y, was cold sprayed onto a MARM 247 superalloy substrates to form a coating having a thickness of 0.25 mm. The same powder was also low pressure plasma sprayed (LPPS) onto other MARM 247 substrates to form a 0.25 mm coating thereon. LPPS is the technique currently used in production to apply this type of coating. Both substrates were then heat treated at 1093° C. for 4 hrs to diffuse and homogenize the coatings.

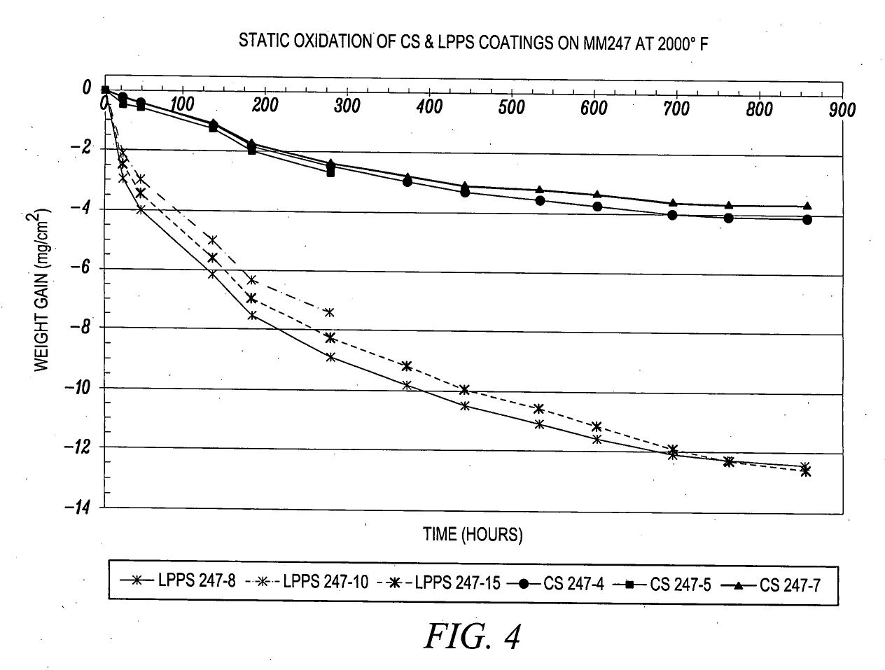

Both the substrates were tested in a static oxidation furnace at 1093° C. The atmosphere in the furnace was static air and the substrates were periodically weighed to determine weight change. As shown in FIG. 4, the overlay coating sprayed by LPPS lost significant weight (4 mg/cm²) after about 70 hrs, while the cold sprayed overlay coating did not experience the same weight loss until after about 700 hrs of exposure.

### EXAMPLE 2

The cold sprayed and LPPS sprayed overlay coatings of example 1, were shot peened and vibro polished to a surface finish of between 1-5 microns and then coated with a 7% YSZ thermal barrier coating. The thermal barrier coatings were each about 0.20 mm in thickness and were formed in an EB-PVD vessel. These samples were then tested in a cyclic oxidation furnace at 1120° C. using a 1-hour cycle. The samples were held at temperature for 50 min. and then quickly pulled out of the furnace and held in ambient air for 10 min. before being quickly returned to the hot furnace. The thermal barrier coatings spalled off during cyclic oxidation test. The thermal barrier coating on the LPPS sprayed bond coat spalled off at just under half the time the thermal barrier coating spalled off on the cold sprayed bond coat. Thus, cold or warm spraying the MCrAlY coating onto a substrate increases the life of a subsequently formed thermal barrier coating by a factor of two.

The coating system 102 formed by the method 200 described above is capable of withstanding temperatures that are equal to or greater than at least 1090° C. Additionally, the coating system 102 may be used to avoid costly and precise drilling steps that were previously needed to form exit holes on turbine airfoils. Here, turbine airfoils having pre-drilled exit holes may be filled with a low-melting point material such as wax, solder, or Woods metal, which may then be removed after the overlay coating 104 is formed thereover. Portions of the overlay coating 104 disposed over the exit holes can then be easily broken away. Additionally, the method 200 by which the coating system 102 is formed is relatively inexpensive to perform. Moreover, the method 200 is less time-consuming to perform than previously known processes of forming overlay coatings.

While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

We claim:

1. A method of forming a coating system on a gas turbine component having a surface, the method comprising the steps of:
cold spraying a material onto the component surface to form an overlay coating, the material comprising MCrAlY, wherein M comprises a constituent selected from the group consisting of Ni, Co, Fe or combinations of Ni, Co and Fe;
heat treating the overlay coating;
shot peening and vibro polishing the overlay coating; and
applying a thermal barrier coating on the overlay coating to form the coating system.

2. The method of claim 1, wherein the MCrAlY material further comprises X, wherein X comprises a constituent selected from the group consisting of Hf, Zr, Si, Re and Pt.

3. The method of claim 1, wherein the material has a melting point and the step of cold spraying comprises heating the coating material to a temperature above about 100° C. and below the half the melting point of the material.

4. The method of claim 3, wherein the substrate has a melting point and the step of cold spraying comprises heating the substrate to a temperature that is below about half the melting point of the substrate in ° C. and below about half the melting point of the material in ° C.

5. The method of claim 1, wherein:
the gas turbine component is a turbine airfoil having exit holes formed therethrough; and
the method further comprises filling the exit holes with a filler before the step of cold spraying;
performing the step of cold spraying;
removing the filler after the step of cold spraying; and
breaking portions of the cold sprayed material over the exit holes before the step of applying the thermal barrier coating.

6. The method of claim 5, wherein:
the step of removing the filler comprises heating the airfoil to a temperature between about 100° C. and 200° C. and melting or burning the filler.

7. The method of claim 5, wherein the step of breaking portions of the cold sprayed material comprises one of thermal shocking the cold sprayed material, thermal cycling, over pressurizing the turbine airfoil, grit blasting the cold sprayed material, or shot peening the cold sprayed material.

8. The method of claim 1, wherein the step of heat treating the overlay coating comprises heat treating the overlay coating to a temperature between about 1000° C. and about 1150° C. for between about 1 hour and about 16 hours.

9. The method of claim 1, wherein the step of shot peening and vibro polishing comprises finishing the overlay coating to a surface finish of between about 1 micron and about 20 microns.

10. The method of claim 1, wherein the step of applying a thermal barrier coating comprises forming the thermal barrier coating by air plasma spraying.

11. The method of claim 1, wherein the step of applying a thermal barrier coating comprises forming the thermal barrier coating by electron beam physical vapor deposition.

12. The method of claim 1, further comprising the steps of machining, cleaning, and grit-blasting the component surface, before the step of cold spraying.

13. A method of forming a coating system on a component having a surface, the method comprising the steps of:
cold spraying a first powder onto the component surface to form an overlay coating, the first powder comprising MCrAlY, wherein M comprises a constituent selected from the group consisting of Ni, Co, or Fe or combinations of Ni, Co, and Fe;
heat treating the overlay coating;
shot peening and vibro polishing the overlay coating; and
air plasma spraying a second powder over the overlay coating to form the thermal barrier coating.

14. The method of claim 13, wherein the MCrAlY powder further comprises X, wherein X comprises a constituent selected from the group consisting of Hf, Zr, Si, Re and Pt.

15. The method of claim 13, wherein the second powder comprises yttria partially stabilized zirconia.

16. A method of forming a coating system on a component having a surface, the method comprising the steps of:
cold spraying a first material onto the component surface to form an overlay coating, the first material comprising MCrAlY, wherein M comprises a constituent selected from the group consisting of Ni, Co, or Fe or combinations of Ni, Co, and Fe;
heat treating the overlay coating;
shot peening and vibro polishing the overlay coating; and
electron beam physical vapor depositing a second material over the overlay coating to form a thermal barrier coating.

17. The method of claim 16, wherein the step of electron beam physical vapor depositing comprises oxidizing a portion of the overlay coating before forming the thermal barrier coating.

18. The method of claim 17, wherein the step of electron beam physical vapor depositing comprises depositing a powder comprising yttria partially stabilized zirconia over the overlay coating.

19. The method of claim 16, further comprising the steps of machining, cleaning, and grit-blasting the component surface, before the step of cold spraying.

20. The method of claim 16, wherein the first material further comprises X, wherein X comprises a constituent selected from the group consisting of Hf, Zr, Si, Re and Pt.
